(19) United States
(12) Patent Application Publication
(10) Pub. No.: US 2007/0001683 A1
(43) Pub. Date: Jan. 4, 2007

(54) System for testing wiring characteristics

(76) Inventor: Henrick Youval Krigel, San Antonio, TX (US)

Correspondence Address: Robert L. McRae, Suite 1500, 700 N. St. Mary's Street, San Antonio, TX, 78205, US

(21) Appl. No.: 11/455,459

(22) Filed: Jun. 19, 2006

Related U.S. Application Data
(60) Provisional application No. 60/691,961, filed on Jun. 17, 2005.

(51) Int. Cl. G01R 31/00; G01R 31/04

(52) U.S. Cl. 324/503; 324/538

(57) ABSTRACT

The invention comprises, inter alia, a portable and easy to use tester for troubleshooting and determining the location of wiring intermittence shorts and wiring intermittence opens. The tester can also check the wire ability to carry a load and detect corrosion and bad contacts. Finally, the invention provides a method to apply the characteristics and qualities of a coaxial cable, to a regular, discrete, multi-wire harness. This method will improve the functionality of a conventional Time-Domain Reflectometer (TDR) system that typically can test only two wires at a time, connected to its input. By providing regular wires the characteristics and qualities of a coaxial cable this method will allow the creation of an expansion box that can interface to a conventional TDR system, and increase the number of wires it can test.

### REFERENCE TO RELATED APPLICATION

This application claims the benefit U.S. Provisional Application No. 60/691,961, filed Jun. 17, 2005, and entitled “Apparatuses and methods for determining and locating wiring intermittence shorts, wiring intermittence opens, the ability of wires to carry a load and determining the distance to shorted or broken wires within a multi strands wire harness, by providing the individual discrete wires within the harness the characteristics and qualities of a coaxial cable.”

### BACKGROUND OF THE INVENTION

1. Field of the Invention

The present invention relates to testing equipment for electrical wiring. More specifically, the invention relates to an apparatus and method for testing a wiring harness for intermittent shorts and breaks (opens), and the ability of the wires therein to carry a desired amount of current.

2. Background of the Invention

There are few effective systems for troubleshooting wiring harnesses. Most such systems currently in use are both extremely expensive and complex, designed to be utilized by at least two technicians positioned at either end of the wiring harness under investigation.

Intermittence problems account for close to 90% of wiring problems within aircraft, and are caused by aging wiring, wear and tear, and vibrations. Finding intermittent problems are very difficult because it may be present during the flight but not on the ground. Extensive discussions with aircraft manufacturers and aircraft maintenance companies confirm the aviation industries challenge with intermittence problems.

The current procedure involves technicians attempting to solve intermittence problems by using an ohmmeter, checking two wires at a time. By touching the wire bundles, the problem may temporarily disappear and not detected. These problems are difficult to find and may take a very long time to be detected. In a wiring harness that contains 50 wires, to find a broken wire, it may take up to 50 tests, one wire at a time. In the same harness, to find a short between 2 wires, it may take up to 1225 tests, since each wire has to be tested against the rest. In a case of intermittent problem, the tests need to be repeated constantly until the failure occurs.

The current invention, not only perform this process automatically and fast, but also assist the technician in finding the actual location of the fault.

### SUMMARY OF THE INVENTION

It is an object of the present invention to provide a novel piece of equipment and method for determining and pointing to the location of wiring intermittence shorts.

It is another object of the present invention to determine and locate wiring intermittence open.

It is another object of the present invention to determine corrosion of contacts and pointing to the location of the corroded contacts by checking the ability of the wire to carry a load.

It is another object of the present invention to determining the distance to shorted or broken wires within a multi wire harness, by providing the individual discrete wires within the harness the characteristics and qualities of a coaxial cable and using Time-domain Reflectometer principles.

It is another object of the present invention to provide a novel piece of equipment and method to provide an expansion unit to be used with a standard TDR that normally connects and test two wires only. A TDR (Time-Domain Reflectometer), typically measures distance to a short or a break in coaxial cable. The present invention will allow the standard TDR to be used not only for coaxial cables, but also for testing wire harnesses made of large number of discrete wires. In addition to finding the distance to shorts and opens in these discrete wires, the present invention will also communicate with a PC or a laptop to store the test results and display the expected length values of the wires under test.

The present invention provides an easy-to-use test system capable of troubleshooting several different types of faults within a wiring harness, such as intermittence and corrosion. In addition it can find the distance to the fault and pinpoint to the exact location of the problem.

The TDR Expansion Unit allows the test of multiple-wire harness using the TDR (Time-Domain Reflectometer) principles. The innovating method provides the characteristics and qualities of a coaxial cable to a multi-wire harness that is made of single wires. This method can be applied to a TDR Expansion system or be used as part of the TDR itself, allowing it to test wiring harnesses made of regular discrete wires. In addition to a stand-alone test system as described above, by providing the qualities of a coax cable to a multi-wire harness made of individual single wires, this method can be used to improve upon the use of an existing TDR system. A typical TDR test system connects and tests only one pair of wires at a time. The present invention allows the connection and test of multi-wire harness that is made of individual single wires.

The method described will provide coaxial characteristics to a wiring harness made of discrete wires. It can then be used as an expansion unit for a standard TDR, or it can be incorporated within the standard TDR to allow it to test a wiring harness made of discrete wires.

The corrosion unit allows for troubleshooting and determining the quality of the electrical connections made by contacts of connectors and splices within the wiring harness. Bad connections, bad crimps of connector pins, and splices, may be caused by the use of wrong tools, wear and tear, and corrosion, and account for a majority of all wiring problems. Bad contacts may cause intermittence problems, when due to vibrations; a contact may be present for a period of time and disappear a moment later. In addition, a bad contact may limit the amount of current the wire can carry, which will result in excessive voltage drop on the faulty contact. In this case, the component connected to the other side of the harness will not receive the voltage level it requires, and the system may not operate correctly.

The apparatus consists of two portable units: (i) Unit A connects to one side of the harness, via connecting pins; (ii) Unit B connects to the other side of the harness, via connecting pins; and optional wireless headphones, receiving test results transmitted by the unit A voice module.

Each apparatus safely tests the cable or wiring harness in question. When testing a wire harness inside an aircraft, two sides of the harness under test are disconnected from their respective LRU (Line Replacement Unit—an aircraft system) and are connected to test Unit A and test Unit B. The apparatus test units use isolated power sources and isolated return connections.

During new wiring installation or wiring modifications on aircraft, wires are checked for continuity between the wires and their connectors. Typically an ohmmeter is used to “ring out” the wires. This type of test shows that the wires are connected, but it does not provide any indication for the quality of the connections. Many times the wires do not reveal a problem when tested with the ohmmeter, but they fail when the actual system is connected and powered up. Currently, technicians attempt to detect failures caused by low quality connections and crimping, by connecting a light bulb to the suspected wire and observing the intensity of the light.

The load apparatus consists of two portable, battery-operated units. One unit connects to one end of the harness; the other unit connects to the other end of the harness. The units control and monitor up to 128 wires for the ability of each wire to carry a load, adjustable by the user, up to 5 Amperes. It can be upgraded to provide even more current. The tester monitors the amount of current flowing in the wire, as well as the amount of voltage loss on the wire, thereby reflecting the quality of the wire and the connections, such as connectors and splices, and alerts the user by producing a fault condition. The user can test the wires by manually advancing to the next wire and observing the results of pass or fail, or setting the tester to the “Auto Mode” and “Stop On Fail,” which will automatically test the wires, and stop when a failure is found. This information may also be displayed on a hand-held unit, via wireless communication. This will allow the user to inspect the harness at its full length, wiggle it at any suspected location, and view the results on either the receiving unit or the portable hand held unit.

Another use of the current invention is during new wiring installations or wiring modifications. Typically wires are checked for continuity by two technicians using an Ohmmeter to “ring out” the wires. This type of test shows that the wires are connected, but it does not provide any indication for the quality of the connections. Many time the wires do not reveal a problem when tested with an Ohmmeter, but they fail when the actual system is connected and powered up.

Because the present invention provides high current to the wires under test, the version used in the system described in FIG. 1 is limited to one wire only to eliminate the possibility of providing high currents to a harness installed inside the aircraft, and may be still connected to the LRU, even though, the system is using isolated return. This fact may also reduce the liability insurance the user may need to carry. For other applications, when a harness is being built outside of the aircraft, a full 128-wire embodiment may be used.

### BRIEF DESCRIPTION OF THE DRAWINGS

The present invention, as well as further objects and features thereof, are more clearly and fully set forth in the following description of the preferred embodiment, which should be read with reference to the accompanying drawings, wherein:

FIG. 1 is a top view of the preferred embodiment;

FIG. 2 is a flowchart of the process of determining and locating wiring intermittence shorts of the preferred embodiment;

FIG. 3 is a flowchart of the process of determining and locating wiring intermittence opens of the preferred embodiment;

FIG. 4 is a flowchart of the process of determining and locating wiring corrosion of the preferred embodiment;

FIG. 5 is a flowchart of the process of applying coaxial characteristics to wiring harnesses made of individual wires used in the preferred embodiment;

FIG. 6 through FIG. 9 are the electronic schematic of intermittence section of the preferred embodiment;

FIG. 10 through FIG. 11 are the electronic schematic of corrosion section of the preferred embodiment;

FIG. 12 through FIG. 15 are the electronic schematic of TDR Expansion section of the preferred embodiment;

FIG. 16 is a schematic block diagram showing the arrangement and function of the various hardware components of the Intermittence part of the current invention;

FIG. 17 is a schematic block diagram showing the arrangement and function of the various hardware components of the TDR Expansion part of the current invention; and

FIG. 18 is a schematic block diagram showing the arrangement and function of the various hardware components of the Corrosion part of the current invention.

### DETAILED DESCRIPTION OF THE PREFERRED EMBODIMENT

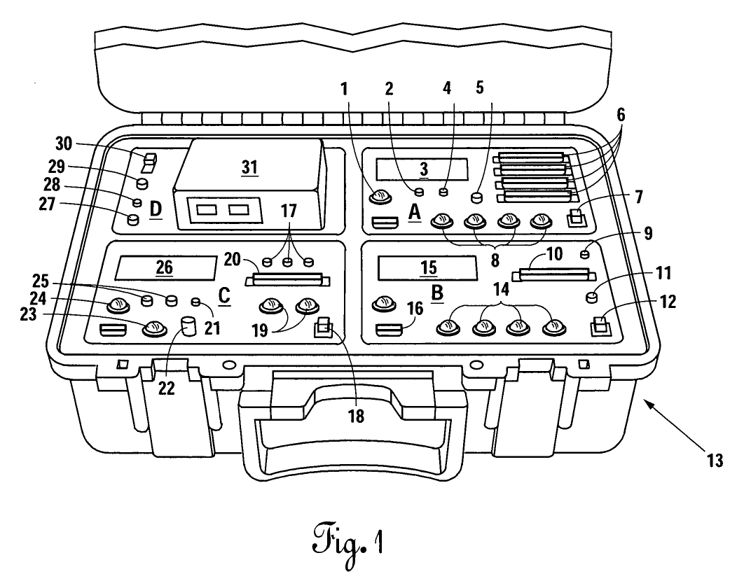

FIG. 1 illustrates the preferred embodiment of the present invention. The testing unit (13) is divided into four subsystems (A, B, C, D). Subsystem (A) is the “INTERMITTENCE.” It contains the circuitry, the controls and the display. It uses a combination of hardware and software to test and find the location of intermittence in a wire within a wiring harness. The wiring harness connects to Subsystem (A) connectors (6). The power switch (7) provides the external power (27), or the internal battery power. The operator uses four control buttons: LIST, LOOP, INTERMITTENCE, EXIT (8). The LIST control button displays all shorts or opens between the wires. The LOOP control button automatically repeats the test and displays the shorts or opens as they are detected. The INTERMITTENCE control button registers and displays an intermittent short or open. The EXIT button exits the mode of operation. When a control button is pressed for less than two seconds, this Subsystem tests for shorts, when a control button is pressed for more than 2 seconds, this Subsystem is testing for opens. The test results are displayed on the LCD display (3) and on yellow LED (2) and red LED (4). When the user is in INTERMITTENCE mode shorts, the tester is testing all wires for any temporary shorts between the wires. Once a short between two wires is found, the Subsystem displays the 2 wires on the LCD display (3), and the red LED (4) turns on. The user then can move and wiggle the harness. As soon as the temporary short disappears, the red LED (4) turns off and the yellow LED (2) turns on. The location that cause the LED's to switch colors is the location of the intermittence. The results can be printed using the built in printer (31) by pressing the print button (1).

Subsystem (B) is the TDR EXPANSION unit, which contains the circuitry, the controls and the display. It uses a combination of hardware and software to expand the capabilities of a conventional TDR by increasing the number of wires it can test. Typically, the Conventional TDR can test only 2 wires, usually a coaxial cable or a twisted-pair. The harness under test connects to connector (10). The output of the Subsystem is a BNC connector (9), which connects to the BNC input connector of external TDR, using a short coaxial cable. The wiring harness connects to Subsystem (B) connectors (10). The power switch (12) provides the external power (27), or the internal battery power. The operator uses 4 control buttons: AUTO, NEXT, BACK, EXIT (14). The AUTO control button checks for any shorts between the wires and displays the shorted wires on the LCD display (15). The external TDR will show the distance to the short. If there are no shorts, it automatically selects one wire at a time, and displays the length of each wire or the distance to the ‘open.’ The wires ID numbers are displayed on the LCD screen (15), the length results are displayed on the external TDR. The NEXT control button selects the next wire to be tested. The BACK control button selects the previous wire to be tested. The EXIT button exits the mode of operation. The results displayed on the LCD display (15) can be printed using the built in printer (31) and by pressing the print button (16).

Subsystem (C) is the “CORROSION.” It contains the circuitry, the controls and the display. It uses a combination of hardware and software to test a wire for corrosion and corroded contacts by its ability to carry current. The Subsystem detects a loss due to corroded contact. In addition to the display of current on the LCD (26), a bright white LED (21) provides a visual indication of the quality of the contacts. The power switch (18) provides the external power (27), or the internal battery power. The wire under test connects between the OUT jack and FLOATING COM jacks (25). The OUT jack connects to one side of the wire; the other side of the wire connects to the FLOATING COM jack, via a dedicated ‘return’ wire, provides a ‘floating’ return which creates an isolated close circuit, adding to the safety of the test. The SET CURRENT knob (22) allows the user to adjust the amount of current that will flow in the wire, the TEST button (23) needs to be pressed during the test, and the white LED (21) provides a visual indication of the quality of the contacts. Subsystem (C) also includes a VOLTAGE TEST section, which allows testing the voltage on each of the 32 wires connected into the Sub-D connector (20). The operator uses two control buttons (19) to select the wire to be tested. The NEXT control button selects the next wire to be tested; the BACK control button selects the previous wire to be tested. A standard DMM can connect to the COM and OUT jacks (19). As the user selects the wire, the wire number is displayed on the LCD DISPLAY (26).

Subsystem (D) includes the external power source and battery charger jack (27), the low power indication in a form of red LED (28), a fuse (29), and a voice switch (30). By switching the voice switch to the ON position the Subsystem will announce the test results in a human voice. To the right of the voice switch (30), a jack allows the connection to a wireless transmitter capable of transmitting the test result messages to wireless headphones. The user can walk along the harness, wiggle and flex the harness in different locations, listen to the test results and the point that cause the test results to change (for example from short to open or from corrosion pass to corrosion fail) is the exact location of the fault. In addition to the above controls, section (D) also includes a printer which allows the printouts of all desired test results.

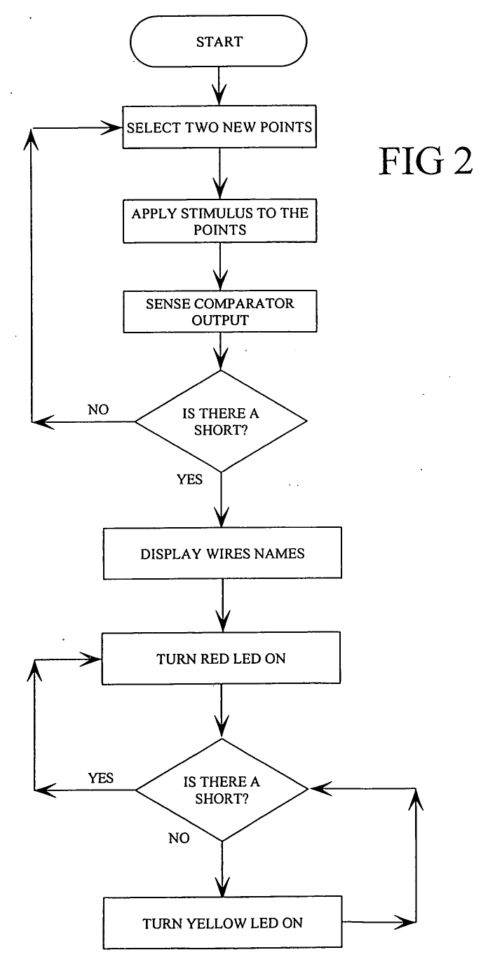

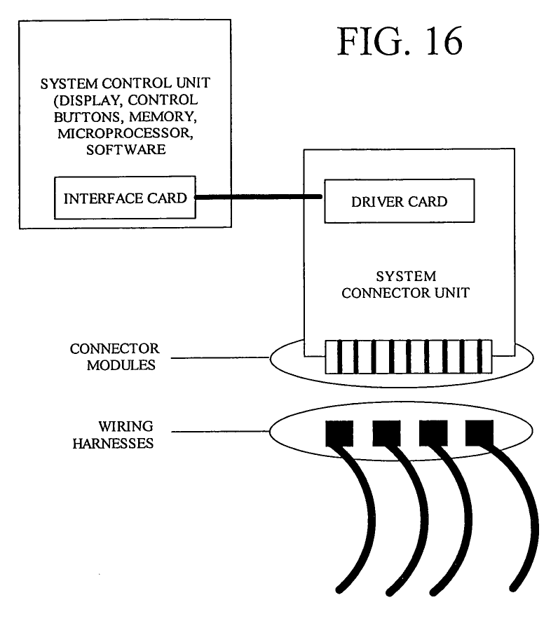

FIG. 2 is a flowchart of the process of determining and locating wiring intermittence shorts of the preferred embodiment. The system control unit, via the interface card, (FIG. 16) sends a command to the driver/sensor card (FIG. 16) to select two wires. The interface card gets a voltage level from the Driver card which corresponds to the status of the two wires (shorts or open). The system compares the voltage level to a set reference value, and determines whether there is a short between the two wires or not. The process continues, each time with different wires, until a short is found. The display then shows the two wires, and the red LED turns ON. The system keeps monitoring these two wires only, and when the short disappears, the red LED turns OFF, and the yellow LED turns ON. This allows the user to inspect the harness at its full length, wiggle it and flax it until the red LED and the yellow LED's are turning ON and OFF. The user then knows the exact location of the intermittence.

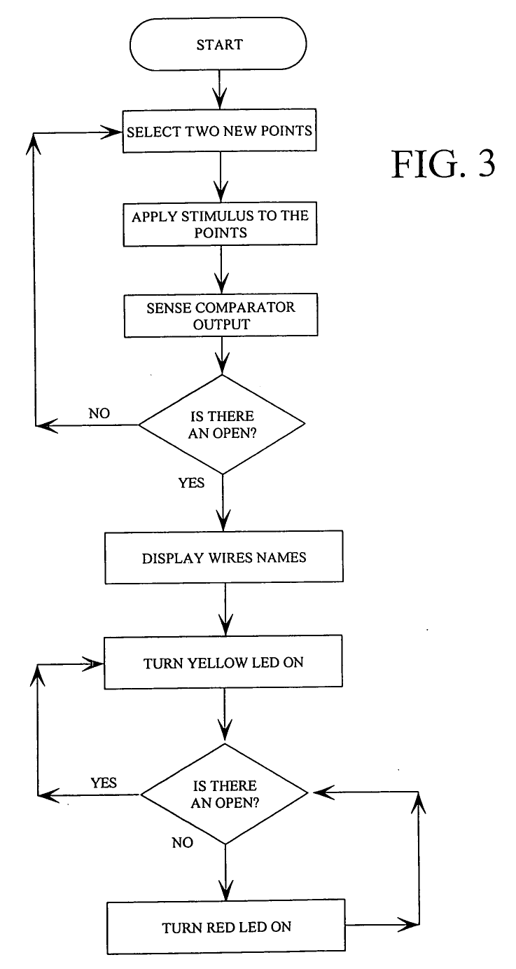

The process of finding opens intermittence is shown in FIG. 3. It is similar process to finding shorts, as described in FIG. 2, only in this case the other end of the harness is terminated with 1k resistors to GND, and the system searches for opens instead of shorts.

The hardware of the system of the present invention consists of two primary components: the System Control unit and the Driver card (FIG. 16), which comprise means for selecting a pair of wires of the harness and means for determining whether a short is present between the selected pair. The System Control unit includes the microprocessor, its built-in memory, the circuitry for the display, the control buttons, and the Interface card which controls the Driver card, which comprise means for providing a known voltage to one wire of the pair of wires, means for measuring a voltage to the other wire of the pair of wires, and means for comparing the measured voltage to the provided voltage.

The system control unit, via the interface card, (FIG. 16) sends a command to the driver card (FIG. 16) to select two wires. The interface card gets a voltage level from the Driver card which corresponds to the status of the two wires (shorted or open). The system compares the voltage level to a set reference value, and determines whether there is a short between the two wires. The system then displays the results, which comprises means for indicating visually the wires between which a short has been detected, and turn ON the appropriate LED, which comprises means for locating the short along the wire harness, and further comprises a first means for causing a first result when the selected pair of wires are determined to be shorted and a second means for causing a second result that is different from the first result when the selected pair of wires is determined to be not shorted.

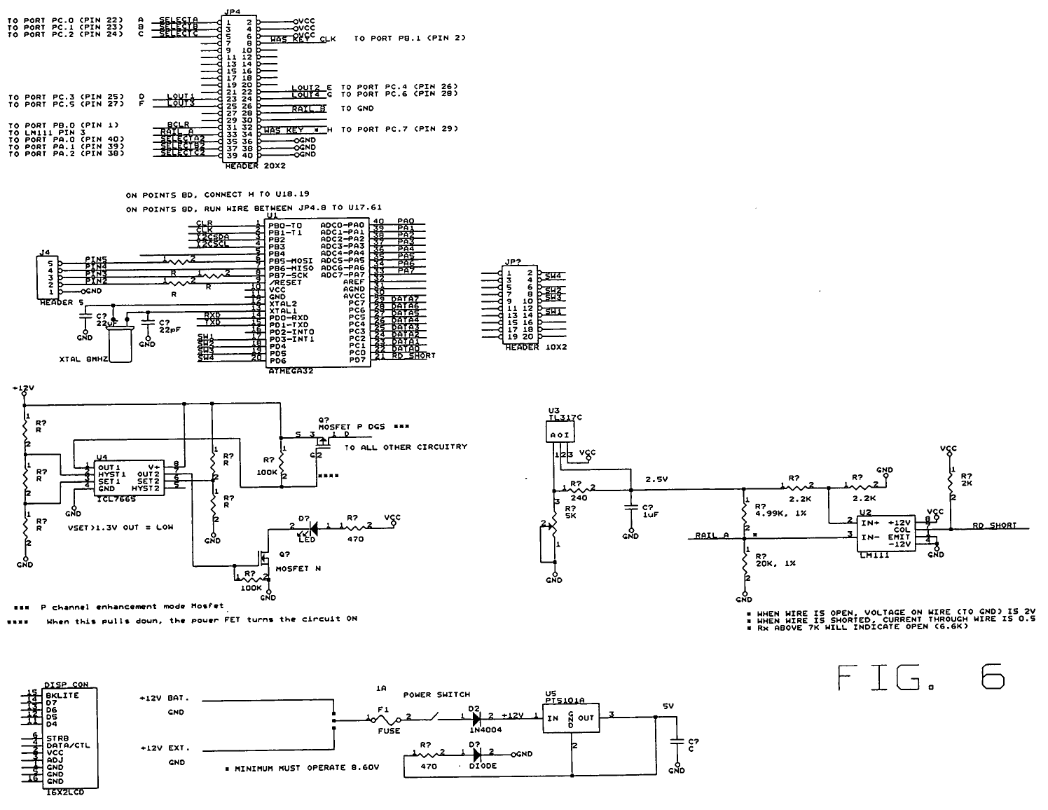

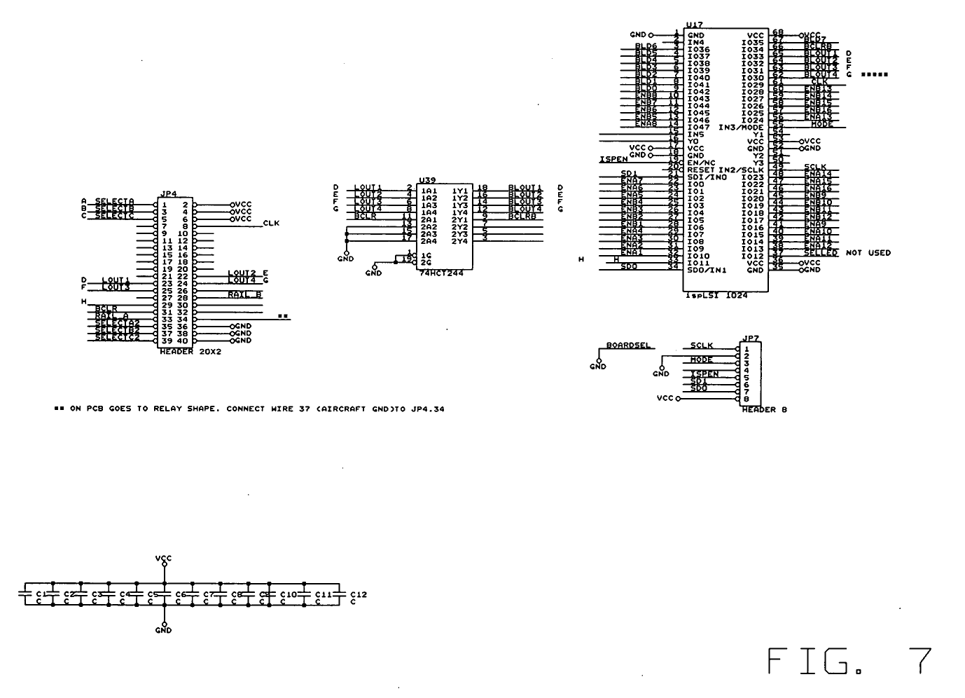

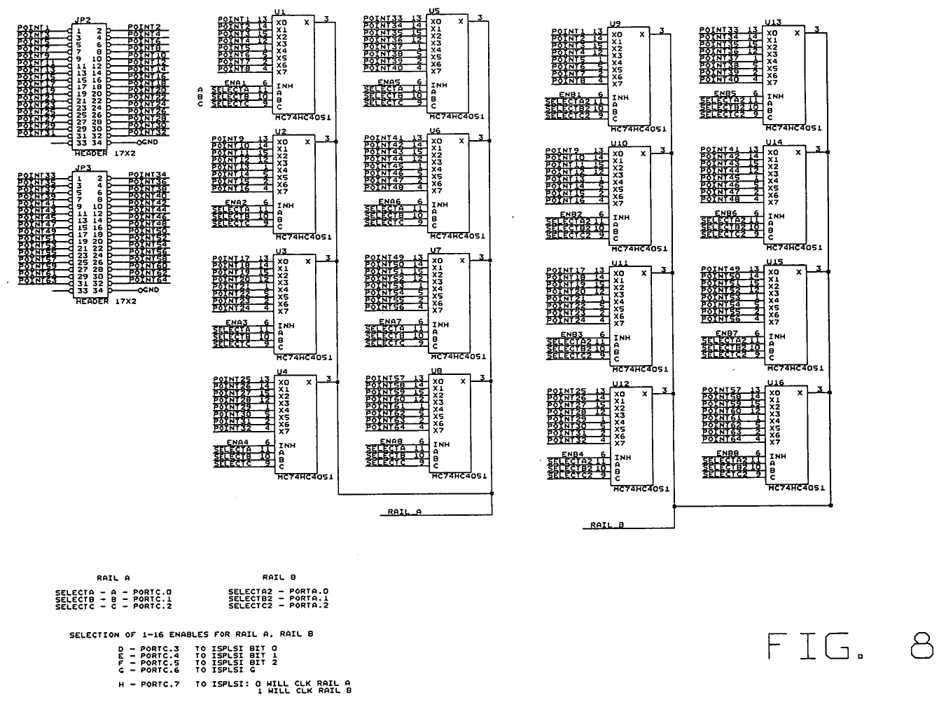

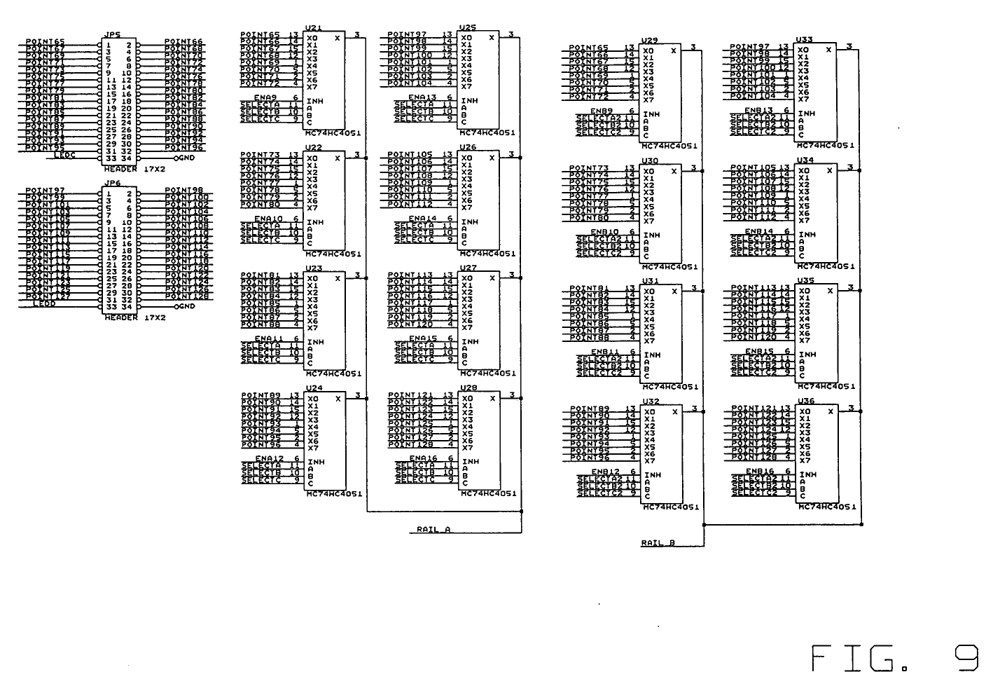

Reference is made to FIG. 6 through FIG. 9 for a description of electronic components of the present invention and, more specifically, components comprising means for selecting a pair of wires from the harness and means for determining whether a short is present. As shown by FIG. 6, U1 is the microprocessor which controls the display, the control buttons, and senses the output level of the comparator, U2. U2 compares the level of the signal from the driver card to a reference voltage, and makes decision if the wires under test are shorted or opened. U3 is a voltage regulator. It provides a reference voltage to the comparator U2. U4 controls the power to the circuitry; it protects the internal battery life by turning the power off when the battery voltage is too low. As shown in FIG. 7, U39 buffers the signals going into U17. U17 contains logic circuitry which interfaces with the Driver card and selects the wires to be tested. As shown by FIGS. 8 and 9, U1-U8, U21-U28 are multiplexers IC's, which are connected to the wire harness under test. These IC's are arranged in two groups as shown in FIGS. 8 and 9: Rail A and Rail B. One driver card is needed to select 128 wires.

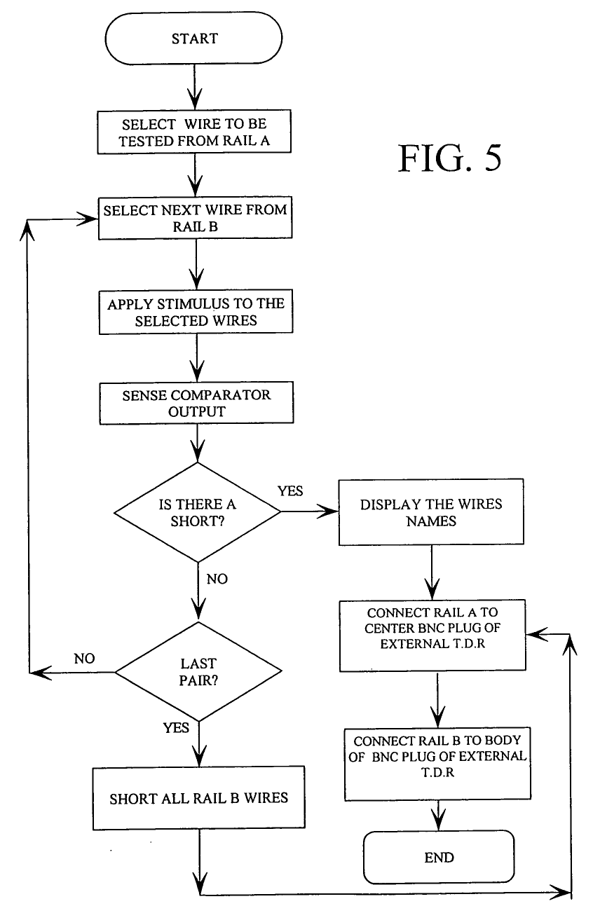

FIG. 5 illustrates a method of testing a multi-wire harness using TDR principles. The wire harness, made of individual single wires, connects to one of the connectors of the test system. The test system tests one wire at a time by sending a signal to the wire under test. The test system selects the wires that are not under test and are not shorted to the wire under test, and uses them as a return for the signal that was sent to the wire under test. These wires that are selected as return, are shorted together by the system, and become one large shield that surrounds the wire under test and provide qualities similar to a shield in a coax cable.

By providing a shield effect to a wire harness that is made of single wires, the impedance between the wire under test and the surrounding wires is more even, and the velocity factor is more uniform, spreads more evenly along the length of the harness, therefore each wire can be tested more accurately, and show a more distinctive waveform on the test system LCD display. The test system evaluates the waveform and provides a digital value, representing the length of the wire under test. The test system can also perform shorts tests. It provides the results as shorts list and also displays the distance to the short. In the event of a short, the test system uses only the shorted wires as a signal return.

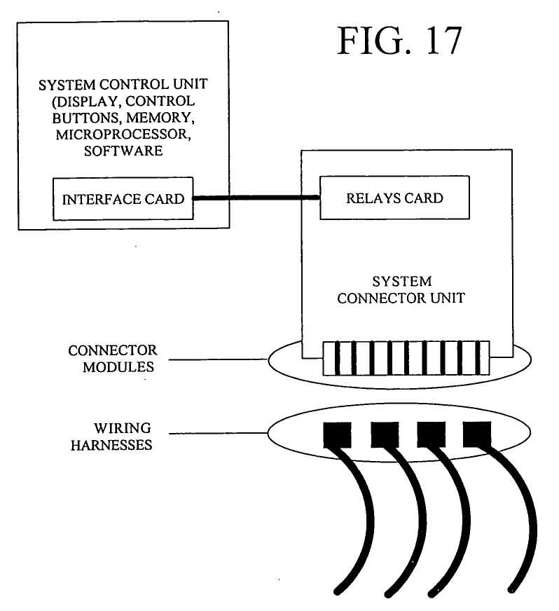

The hardware of the system of the present invention consists of two primary components: the System Control Unit and the Relays card (FIG. 17). The System Control unit includes the microprocessor, its built-in memory, the circuitry for the display, the control buttons, and the Interface card which controls the Relays card. The system control unit, via the interface card, (FIG. 17) sends a command to the driver card (FIG. 17) to select two wires, one from the group of Rail A, and the second from the group of Rail B The interface card gets a voltage level from the Driver card which corresponds to the status of the two wires (shorts or open). The system compares the voltage level to a set reference value, and determines whether there is a short between the two wires. As described in the flowchart of FIG. 5, when the first short is found, the two wires names are displayed; the first wire, from the group of Rail A, is directed to the center of the BNC plug of the external TDR, the second wire, from the group of Rail B is directed to the body (shield) of the BNC plug of the external TDR. When no shorts are found, the system, as described in the flowchart of FIG. 5, connects the wire from the group of Rail A to the center BNC plug of the external TDR, and it shorts all Rail B wires together and connects them to the body (shield) of the BNC plug of the external TDR.

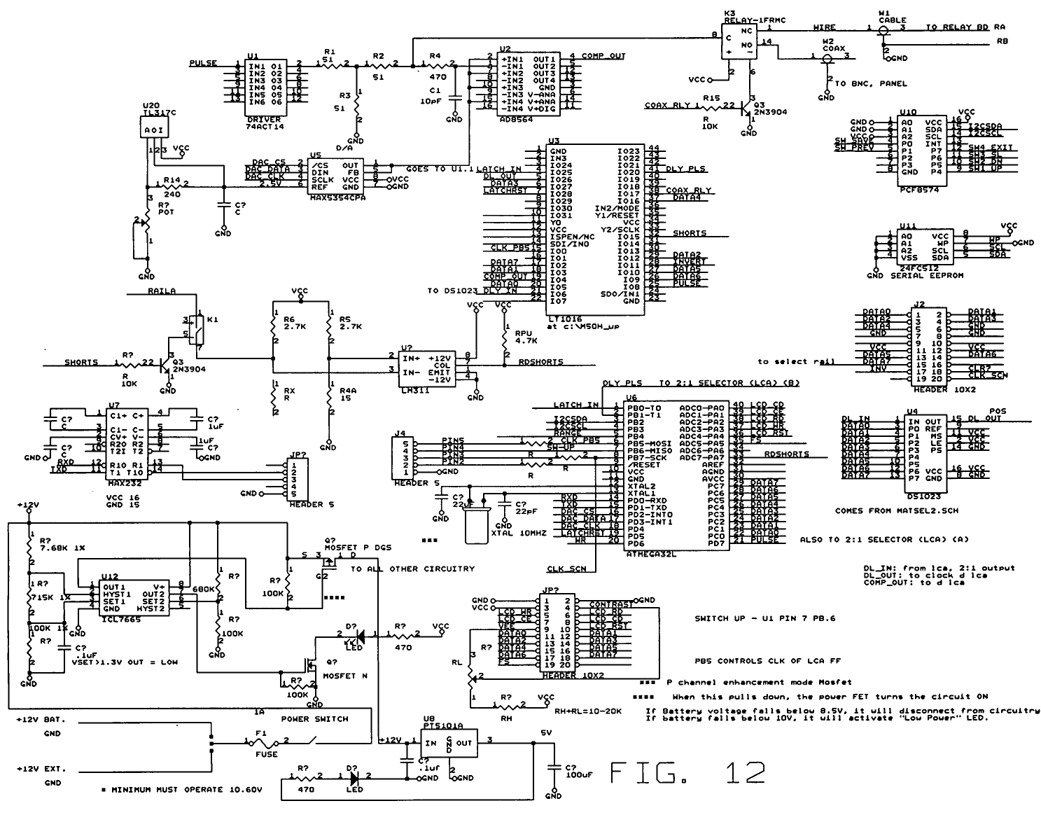

Reference is made to FIG. 12 through FIG. 15 for a description of the electronic components of the present invention. As shown by FIG. 12, U6 is the microprocessor which controls the display, the control buttons, and senses the output level of the comparator, U9, and which comprises means for selecting a wire from the harness for testing, means for testing the remaining wires of the harness for a shorted wire until either a shorted wire is found or until all remaining wires have been tested, means for calculating the distance to the short or open in the selected wire, and means for providing an electrical pulse to the selected wire using either a shorted wire or all remaining wires as a return. U9 compares the level of the signal from the Relay card to a reference voltage, and determines if the wires under test are shorted or opened. U4 is a 1 ns programmable delay line which in conjunction with U1 driver chip, U5 digital-to-analog converter chip, U2 fast comparator chip and U3 which contains logic circuitry, are providing the ability to check the time in nanoseconds between the main pulse sent via U1 and the reflected pulse arriving at pin 2 of the U2 comparator, thus comprising means for measuring the delay value between the electrical pulse and any reflected signal. Because the software controls the amount of delay (in Ins steps), when there is a match between the reflected pulse and the delayed pulse, the systems knows the exact delay that was selected for that match. The value of the delay is the time between the main pulse and the reflected pulse. U20 is a voltage regulator, providing reference voltage to U5. U5 is a programmable analog/digital IC, the output of which is fed into the reference input of U2, the fast comparator, providing a method to measure the voltage of the signal arriving at pin 1 of U2 at 1 ns intervals. The voltage and time information are used to plot the waveform of the signal going through wire and of course, the reflection. U7, MAX232 allows serial communication between the Microprocessor U6 and a PC serial port, U10 expands the number of I/O U6 can handle, U11 is additional memory for U6, the Microprocessor. U8 and U12 controls the power to the circuitry; U8 is 5 V voltage regulator, U12 protects the internal battery life by turning the power off when the battery voltage is too low.

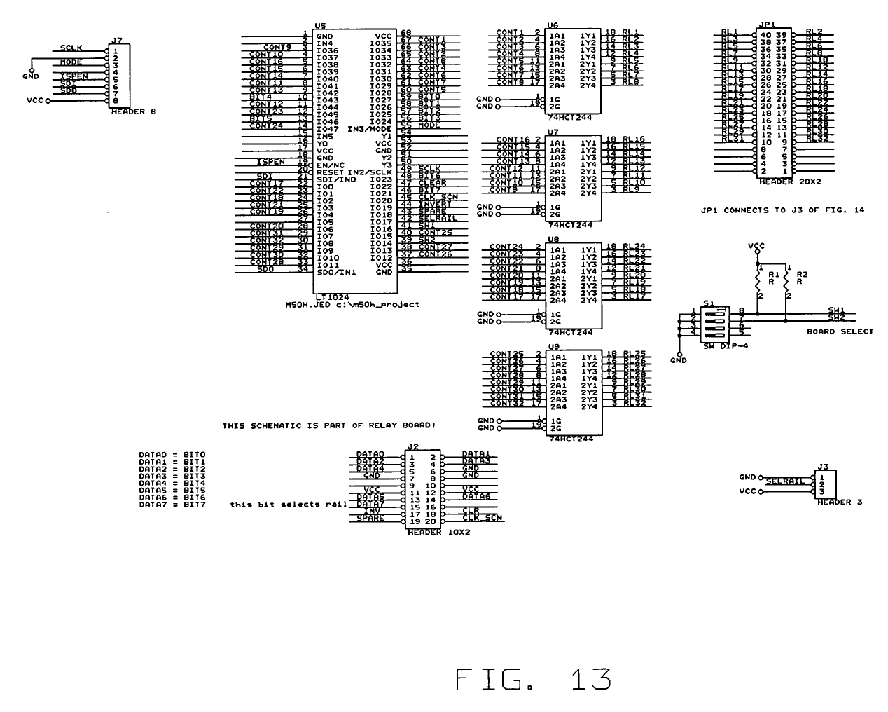

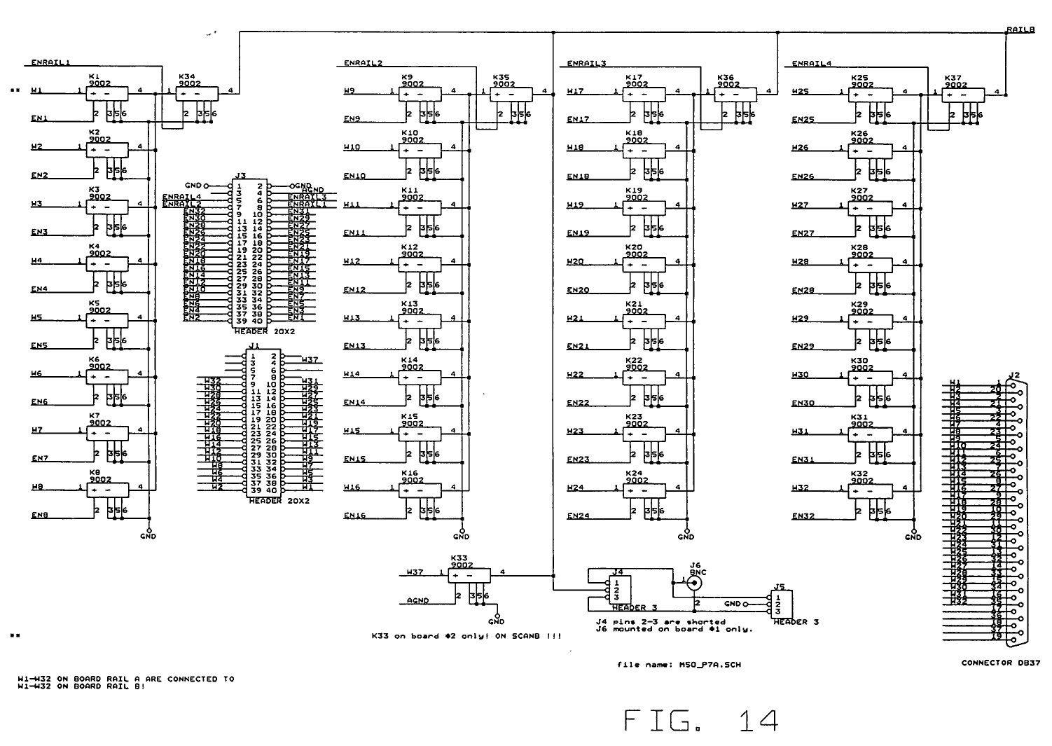

As shown by FIG. 13, U6 contains logic circuitry comprising a first means for electrically connecting the selected wire to the center pin of an RF connector and a second means for electrically connecting the shorted wire or all remaining wires to the shield of the RF connector, which allows the selection of Rail A wires and rail B wires at the Relay cards. U7 through U10 are buffers, their outputs connect to the relays at the Relay cards. As shown by FIG. 14, K1 through K37 are the relays for Rail A. Each relay connects to a wire. Each wire connects to a relay of Rail A board and a relay at Rail B board, so for example, wire 1 of the harness will connect to Relay K1 of Rail A board, and relay K1 of rail B board.

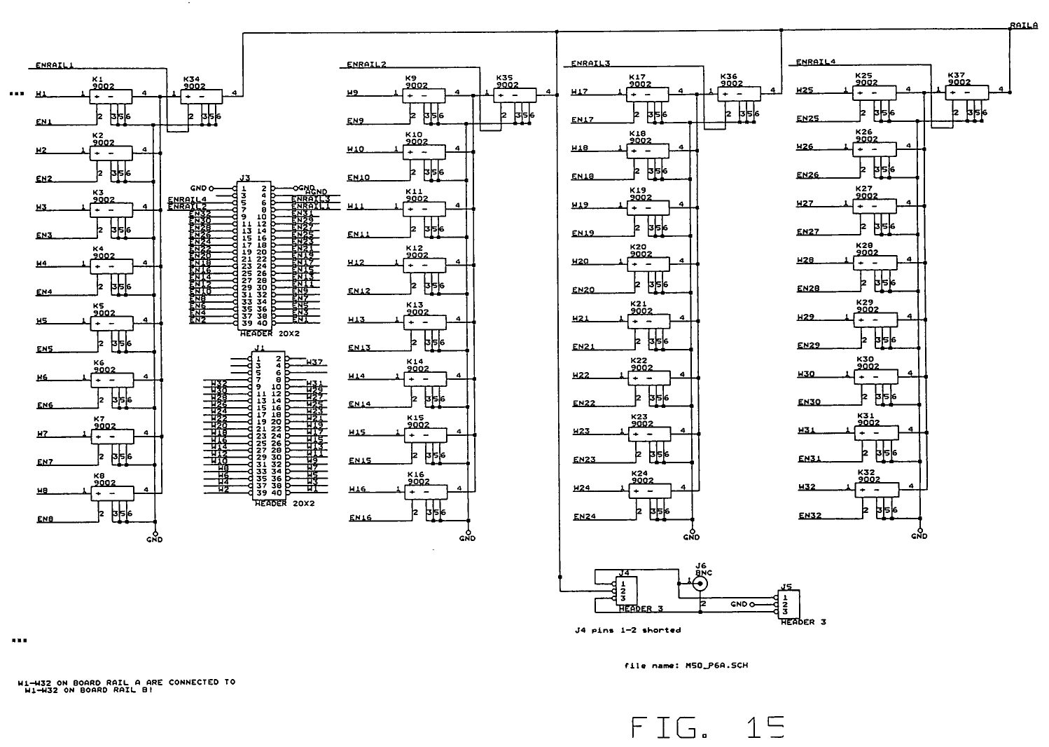

As shown by FIG. 15, K1 through K37 are the relays for Rail B. Each relay connects to a wire. Each wire connects to a relay of Rail A board and a relay at Rail B board, so for example, wire 1 of the harness will connect to Relay K1 of Rail A board, and relay K1 of rail B board.

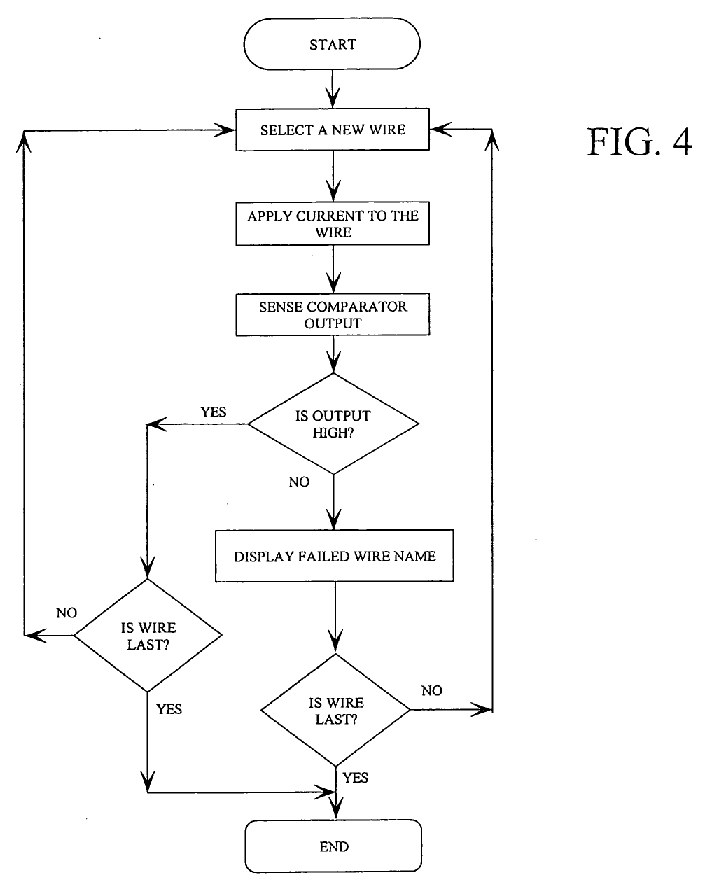

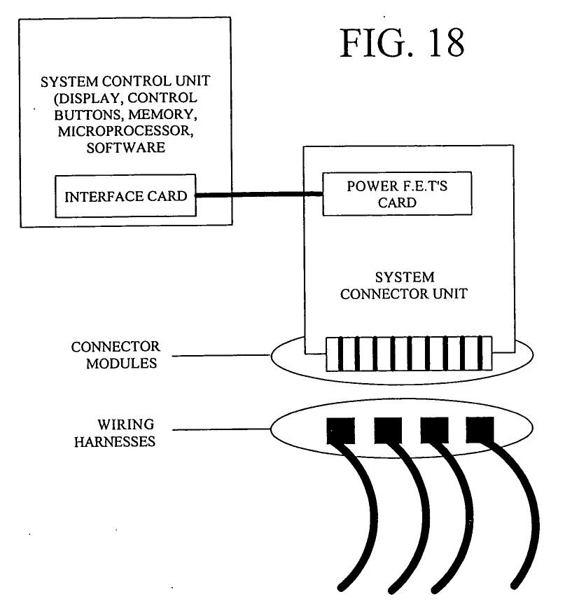

Reference is made to FIG. 4 for a description of the method for testing multiple wires for corrosion. The system control unit, via the interface card, (FIG. 18) sends a command to the Power FET's card (FIG. 18) to select two wires. The interface card provides a selected amount current as selected by the user and applies it to the selected wire. The system senses the output of a comparator which indicates the amount of current flowing through the wire. A comparator output HIGH indicates that the amount of current flowing through the wire exceeds the minimum set reference. In this case, the next wire will be selected. When the output of the comparator is low, it indicates a current loss, and the failed wire is displayed. The user can then wiggle and flex the wire, and view the display for a pass/fail changes. The physical location of the harness that cause the changes of Pass and Fail on the display, is the physical location of the corrosion problem. When flexing the harness while the red LED and the yellow LEDs are turning ON and OFF, the user knows the exact location of the intermittence.

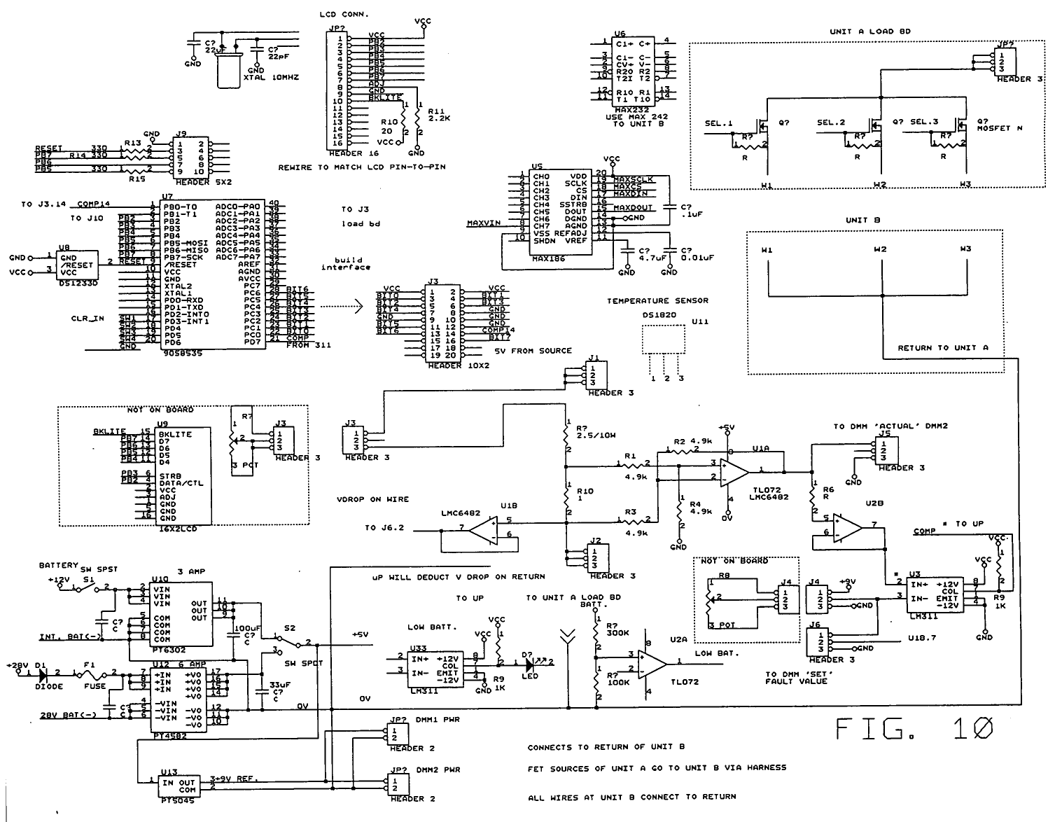

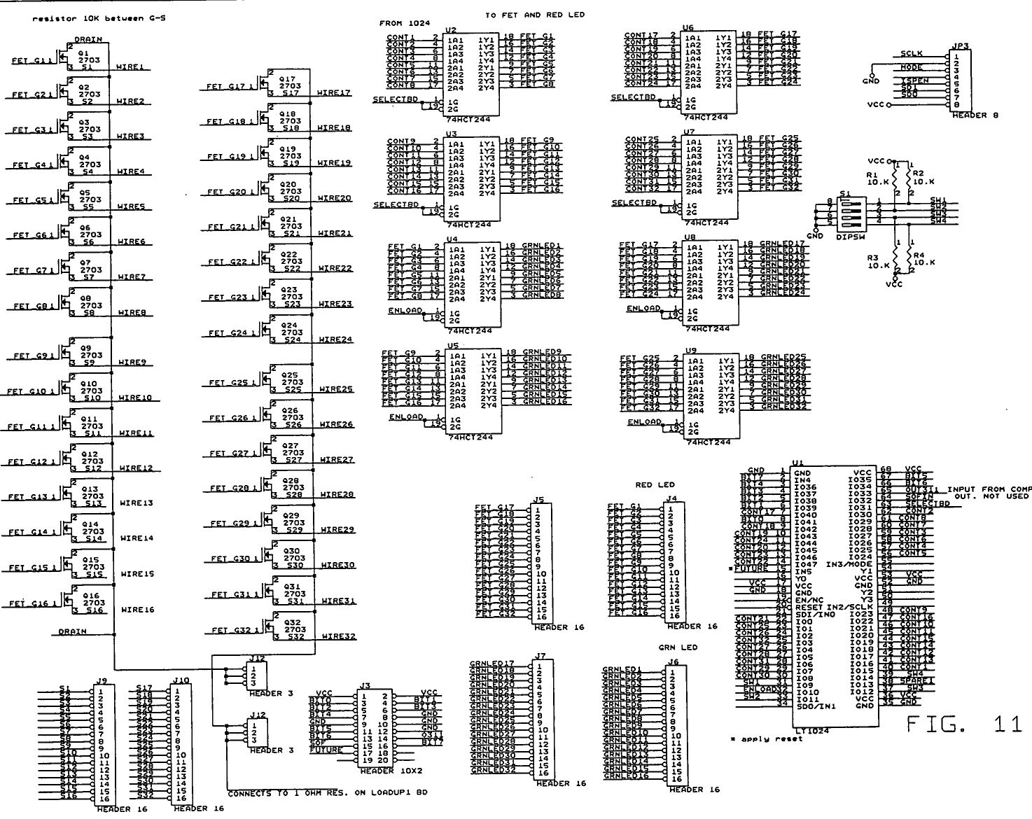

FIG. 18 shows the hardware of the system of the present invention, which comprises two primary components: the system control unit and the POWER FET card. The system control unit includes the microprocessor, its built-in memory, the circuitry for the display, the control buttons, and the Interface card which controls the POWER FET card. The system control unit, via the interface card, sends a command to the POWER FET card to select one wire. Upon the selection of the wire the current source connect to one side of the wire; the other side of the wire connects to the isolated return wire. Once there is a current flow through the wire, the amount is displayed on a current meter, as well as the voltage drop on the wire if desired by the user. Reference is made to FIG. 10 through FIG. 11 for a description of the electronic components of the present invention. The present invention can test for corrosion 128 wires or more, the circuitry used for FIG. 1 C is limited to one wire only. As shown in FIG. 10, U7 is the microprocessor which controls the display, the control buttons, and senses the output level of the comparator, U3. U3 compares the level of a voltage that is related to the amount of current flowing through the wire (a voltage drop on 1 ohm resistor) a reference voltage, set by the user as a minimum accepted current flow. U9 is the LCD display, U1A is an operational amplifier, U1B as a voltage follower capable of measuring the voltage drop loss on the wire under test. U2A is a low voltage indicator, pin 2 connects to a reference voltage. U5 is an 8-channel Analog to Digital IC, allows the replacement of an actual Meter for displaying the results. The Microprocessor U7 can read the measured value and display it on the LCD screen. U11 is an optional temperature sensor to compensate for current readings affected by temperature. U8 is a reset IC, connected to the Reset input of the microprocessor U7, it adds to the stability of U7.

U6 is a MAX232 IC, allows the serial communication with a PC or a laptop.

As shown in FIG. 11, U1 contains the logic for selecting the wire to be tested. U2, U3, U6, U7 are 74HCT244 buffers that connect to the gates of the FET's Q1 through Q32. U4, U5, U8, U9 are 74HCT244 buffers that connect to the LED's for PASS/FAIL indication. FET Q1 through FET Q32 are turned on one at a time by program control, each FET is connected to one of the wires under test through its Source. When a wire is selected to be tested, its FET turns on, the Source and Drain are getting shorted, and the selected wire is connected to the current source.

The present invention is described above in terms of preferred illustrative embodiments in which a system for testing wiring characteristics is described. Those skilled in the art will recognize that alternative constructions can be used in carrying out the present invention. Other aspects, features, and advantages of the present invention may be obtained from a study of this disclosure and the drawings, along with the appended claims.

I claim:

1. A method for locating intermittent shorts in a multi-wire harness comprising the steps of:
selecting a pair of wires of a multi-wire harness for testing;
determining whether a short is present between the selected pair of wires;
repeating said selecting and said determining steps with an untested pair of wires until a short between any selected pair of wires is detected;
visually indicating the specific pair of wires between which a short has been detected; and
locating the short along the multi-wire harness.

2. A method for locating intermittent shorts, as recited in claim 1, further comprising:
repeating the selecting, determining, repeating, indicating, and locating steps for all pairs comprising said wiring harness until every wire has been tested for a short with any other wire of the harness.

3. A method for locating intermittent shorts, as recited in claim 1, wherein said determining step further comprises:
providing a known voltage to one wire of said pair of wires;
measuring a voltage to the other wire of said pair of wires; and
comparing the measured voltage to the provided known voltage.

4. A method for locating intermittent shorts, as recited in claim 1, wherein said locating step further comprises:
causing a first result when the selected pair of wires are determined to be shorted;
causing a second result that is different from the first result when the selected pair of wires are determined not to be shorted; and
moving along the wiring harness while manipulating the wiring harness to cause the selected pair of wires to repeatedly change between a shorted and open state.

5. A method for determining the location of a short or open of a wire of a multi-wire harness comprising:
selecting a wire from the multi-wire harness for testing;
testing the remaining wires of the harness for a shorted wire, said shorted wire being a wire shorted to said selected wire, until either a shorted wire is found or until all remaining wires have been tested;
electrically connecting the selected wire to the center pin of an RF connector;
electrically connecting said shorted wire or said remaining wires to the shield of said RF connector; and
calculating the distance to the short or open in the selected wire.

6. A method for determining the location of a short or open of a wire, as recited in claim 5, wherein said calculating step further comprises:
providing an electrical pulse to said selected wire using said shorted wire or said all remaining wires as a return;
measuring the delay value between said electrical pulse and any reflected signal;
using the delay value to calculate the length to the short or open in the selected wire.

7. A wire testing device for locating intermittent shorts in a multi-wire harness comprising:
means for selecting a pair of wires of a multi-wire harness for testing;
means for determining whether a short is present between said pair of wires;
means for locating the short along the wiring harness; and
means for indicating visually the wires between which a short has been detected.

8. A wire testing device for locating intermittent shorts, as recited in claim 7, wherein said determining means further comprises:
means for providing a known voltage to one wire of said pair of wires;
means for measuring a voltage to the other wire of said pair of wires; and
means for comparing the measured voltage to the provided voltage.

9. A wire testing device for locating intermittent shorts, as recited in claim 7, wherein said locating means further comprises:
a first means for causing a first result when the selected pair of wires are determined to be shorted; and
a second means for causing a second result that is different from the first result when the selected pair of wires is determined to be not shorted.

10. A wire testing device for determining the location of a short or open of a wire of a multi-wire harness comprising:
means for selecting a wire from the multi-wire harness for testing;
means for testing the remaining wires of the harness for a shorted wire, said shorted wire being a wire shorted to said selected wire, until either said shorted wire is found or until all remaining wires have been tested;
a first means for electrically connecting said selected wire to the center pin of an RF connector;
a second means for electrically connecting said shorted wire or said all remaining wires to the shield of said RF connector; and
means for calculating the distance to the short or open in the selected wire.

11. A wire testing device for determining the location of a short or open of a wire, as recited in claim 10, wherein said means for calculating further comprises:
means for providing an electrical pulse to said selected wire using said shorted wire or said all remaining wires as a return; and
means for measuring the delay value between said electrical pulse and any reflected signal.
